(19) United States
(12) Patent Application Publication
(10) Pub. No.: US 2009/0085028 A1
(43) Pub. Date: Apr. 2, 2009

(54) HYBRID MATRICES FOR THIN-LAYER TRANSISTORS

(75) Inventors: Jean-Pierre Simonato, Sassenage (FR); Caroline Celle, Firminy (FR)

Correspondence Address: OBLON, SPIVAK, MCCLELLAND MAIER & NEUSTADT, P.C., 1940 DUKE STREET, ALEXANDRIA, VA, 22314, US

(73) Assignee: COMMISSARIAT A L'ENERGIE ATOMIQUE, Paris (FR)

(21) Appl. No.: 12/212,944

(22) Filed: Sep. 18, 2008

(30) Foreign Application Priority Data
Sep. 27, 2007 (FR) 07/06767

(51) Int. Cl. H01L 51/30

(52) U.S. Cl. 257/40; 257/E51.027

(57) ABSTRACT

The invention relates to a hybrid semiconductor material and to a device containing same.

The hybrid semiconductor material of the invention comprises an organic semiconductor matrix in which semiconductor nano-objects grafted by organic entities are dispersed, the organic matrix comprising small semiconductor molecules and the said organic entities having an active electrical function similar to those of the said small semiconductor molecules.

The hybrid semiconductor material of the invention has applications in the field of mass consumer electronics, in particular.

The invention relates to a hybrid semiconductor material and to a device containing same.

Devices based on semiconductor material have found a widespread use; they are beginning to spread into the field of mass consumer electronics, where simple logic functions must be produced by an inexpensive method.

The transistor is one of the elementary components of these devices.

To produce a transistor, the semiconductor part can be produced by various methods.

One of these methods is the vapour deposition of a semiconductor material. However, this method is difficult to implement on a large scale because it requires high-vacuum, small areas, etc.

Another method currently used to fabricate the semiconductor part of the transistors is wet deposition, in which solutions are used.

This is the preferred method today, because the deposition can be carried out thereby at low temperature, at ambient pressure and on large areas, using conventional printing techniques such as inkjet, flexography, heliography, etc.

The overwhelming majority of semiconductor materials for producing thin-layer transistors for mass consumer market have a purely organic chemical structure, that is, comprising hydrocarbon molecules, conjugated, optionally substituted by any element of the Periodic Table of Elements, and/or cyclized.

However, these organic compounds display mediocre performance, which must be improved for a large scale application. For example, the mobilities of the charge carriers of these organic materials preclude the production of efficient and rapid devices.

Other semiconductor materials consist of very small inorganic materials, called nano-objects, with appropriate semiconductor properties.

A nano-object is defined as an entity of which at least two of the three dimensions in space are shorter than 100 nanometres.

The carbon nanotube is one representative inorganic material.

However, it is extremely difficult to purify carbon nanotubes, and pure carbon semiconductor nanotubes are not available for the time being.

Thus, the inorganic semiconductor materials of this type are still mixtures of nanotubes of the semiconductor type and of the metal type, complicating their manufacturing process. Moreover, these materials lack reproducibility for large scale use.

It has therefore been proposed to functionalize carbon nanotubes noncovalently by a surfactant and to disperse them in a polymer matrix of the polyhexylthiophene type. However, although the mobility is improved thanks to the addition of carbon nanotubes, it appears that at the same time, the Ion/Ioff ratio of the transistor fabricated from this material becomes insufficient for industrial application, this ratio characterizing the capacity of the transistors to switch from the “on” state to the “off” state.

It has also been proposed to use, as an inorganic semiconductor material, silicon nanowires, doped or undoped. These nanowires can be used as the semiconductor part of the transistors. However, their use requires complex techniques, beyond the scope of the low cost printing techniques for mass outlets considered in connection with an industrial process.

These transistors based on semiconductor nanowires comprise nanowires that are placed in direct contact on the source and drain electrodes, implying that the length of the nanowires used is at least equal to the minimum distance between the source and drain electrodes. This is beyond the scope of the present invention, in so far as we assume a context of mass consumer electronics, in which the source-drain distances may be as high a few tens of micrometers (μm). In fact, today, nanowires of this size are difficult to produce and to handle.

Besides, US patent application US 2005/0104060 describes silicon nanoparticles functionalized to improve the mobility of the charge carriers in a semiconductor matrix of the poly(3-hexylthiophene) type.

In this patent application, simple organic groups, but all different from the unit constituting the polymer constituting the semiconductor matrix, are grafted covalently on inorganic semiconductor nanoparticles.

These nanoparticles are thereby dispersed in the semiconductor matrix, and thereby confer a slight gain in mobility of the charge carriers on the material obtained.

However, the grafted organic groups do not have groups suitable for producing charge transfers between the organic semiconductor part constituting the matrix and the silicon nanoparticles.

It is the object of the invention to overcome the drawbacks of the semiconductor materials of the prior art, by proposing a semiconductor material in which the mobility of the charge carriers is improved, to which wet deposition methods using conventional printing techniques can be applied.

Thus, the invention proposes novel hybrid organic, inorganic, semiconductor matrices, with higher performance compared to purely organic matrices.

For this purpose, the invention proposes a semiconductor hybrid of the type comprising an organic semiconductor matrix in which semiconductor nano-objects grafted by organic entities are dispersed, characterized in that the said organic matrix comprises small semiconductor molecules and in that the said organic entities grafted on semiconductor nano-objects have an active electrical function with a similar structure to that of the said small semiconductor molecules.

Preferably, the said entities also have a function for covalent grafting of the said organic entities on the nano-object.

In a first alternative of the invention, the nano-objects are nanowires.

Preferably, the nanowires are silicon nanowires.

Also preferably, the nanowires are germanium-silicon nanowires, Ge—Si.

Still preferably, the nanowires are nanowires of zinc oxide, ZnO.

Still preferably, the nanowires are nanowires of gallium arsenide, GaAs.

In another alternative of the invention, the nano-objects are carbon nanotubes.

In all the embodiments of the invention, the said nano-objects preferably have at least two dimensions shorter than 100 nanometres and a length/diameter ratio above 10.

The invention also proposes a device comprising a material according to the invention.

Preferably, this device is a transistor.

The hybrid semiconductor materials of the invention are prepared by dispersion, into organic semiconductor matrices, of semiconductor nano-objects, doped or not, grafted by organic entities.

The doping elements of the nano-objects having free electronic doublets or vacancies are, for example, derivatives of boron, phosphorus, etc.

The nano-objects may be nanowires of zinc oxide, ZnO, gallium arsenide, GaAs, silicon, Si, germanium, Ge, or germanium-silicon, Si—Ge, or carbon nanotubes.

These various types of nano-objects may be present alone or in a mixture of two or more.

The nano-objects of the invention have a length shorter than the size of the channel between the source and drain electrodes.

The nano-objects of the invention are functionalized to achieve two objectives concomitantly: to obtain a satisfactory dispersion of the nano-objects in the organic matrix; and to permit an efficient charge transfer between the nano-objects and the organic semiconductor matrix.

Thus, the entities that are grafted on the nano-objects are of the bifunctional type: one part, called reactive group here, serves for the covalent grafting on the nano-object, and the other part, called active electrical part here, serves for the compatibilization with the host matrix and for the charge transfer.

To obtain the charge transfer, the entities grafted on the nano-objects of the invention comprise motifs which are suitable for obtaining the charge transfer, such as pi bonds, n electrons, d orbitals or redox type species.

To obtain the compatibilization with the host matrix, the active electrical part of the grafted entity is selected according to the organic matrix used. The active part is said to be similar to the organic matrix, that is, it has the same basic skeleton.

For a matrix consisting of a semiconductor polymer, the active function used has a similar structure to that of the monomer of the semiconductor polymer.

For any organic semiconductor system based on small molecules, the active function is similar to the small semiconductor molecules present in the matrix.

In the context of the invention, the terms “small semiconductor molecules” mean organic semiconductor molecules having a molecular weight not exceeding 1500 g/mol.

By way of illustrative and non-limiting examples, the active electrical function may be of the thiophene type, and derivatives thereof, arylamines and derivatives thereof, isochromenones and derivatives therefore, pentacenes and derivatives thereof, porphyrines, phthalocyanines and derivatives thereof.

The reactive group is selected according to the nano-objects.

Thus, in the case of silicon nanowires, they may be coated with an oxide layer or not. This implies that the functionalization modes must be selected according to the type of nanowire used.

Si nanowires having an oxide layer have, on the surface, reactive functions of the silanol type, Si—OH, while oxide-free nanowires essentially have functions of the silicon hydride type, Si—H.

By way of non-limiting examples, the reactive groups usable for silicon nanowires may be as follows:

in the case of silicon nanowires without oxide layer, that is having Si—H type bonds on the surface, use can be made of diazonium salts R-N₂⁺ X⁻ or unsaturated compounds of the vinyl or acetylene type;

for silicon nanowires having an oxide layer, that is having Si—OH type bonds on the surface, the reactive group may be a trihalidesilane R—SiX₃ or a trialkoxysilane of the R—Si(OR)₃ type.

For nano-objects of the oxide type such as ZnO, the reactive group is selected for example from the silane family.

The active organic entities can be grafted in several steps. For example, a first organic part can be grafted on the nano-objects with a pending reactive group, and this pending reactive group can then be functionalized by one or more reactions to bond the active electrical function.

The hybrid semiconductor materials of the invention can be used in any type of device requiring a semiconductor device, but they will preferably be used as semiconductor parts of thin-layer transistors.

A twofold objective is achieved by the covalent grafting of organic entities on the nano-objects.

On the one hand, the nano-objects, doped or not, are perfectly dispersed in the semiconductor matrix, conferring on the hybrid semiconductor material thus formed the possibility of being applied by wet printing techniques. The presence of the nano-objects confers, on the hybrid semiconductor material of the invention, a substantial improvement of electrical performance and particularly of the mobility of the charge carriers.

Furthermore, the functionalization of the nano-objects with groups permitting charge transfers between the nano-objects and the organic matrix allows an additional improvement of the electrical performance of the hybrid semiconductor material of the invention.

In the invention, the nano-objects are functionalized before their dispersion in the organic semiconductor matrix.

The organic entities are generally grafted when the nano-objects are bound to a substrate.

In the invention, it is possible to detach the nano-objects from the substrate after their chemical functionalization carried out when they were on the substrate, and to disperse them in solution.

It is also possible to purify them and remove the residual catalyst and/or the native oxide layer.

The walls of the nano-object can be chemically functionalized by various methods, such as chemical grafting on the surface oxide by trihalidesilanes or trialkoxysilanes, by reactions of unsaturated compounds or diazonium salts on a silicon surface from which the oxide has previously been removed.

The functionalization can be carried out in several steps.

The nanowires thus functionalized can also be solubilized in an organic compound, and consequently the resulting solution can be used to fabricate transistors by a wet deposition method.

The invention will be better understood from the description provided below, purely for illustration and in a non-limiting manner, of several exemplary embodiments thereof.

### EXAMPLE 1

Manufacture of a transistor having a film of hybrid material of the p type with silicon nanowires grafted with a triphenylamine derivative.

1) Synthesis of the TPA Derivative:

1-(4-(diphenylamino)phenyl)-3-(3-(triethoxysilyl)propyl)urea (derivative of TPA) is synthesized in three steps from diphenylamine and 4-fluoronitrobenzene, by the formation of p-nitro-triphenylamine, reduction of the nitro group to amino and introduction of the triethoxysilane function by the addition of isocyanatopropyltriethoxysilane to p-amino-triphenylamine under reflux in dry ethanol. The product is obtained in the form of a brown solid by precipitation in pentane, filtration and drying with an overall yield of 37%.

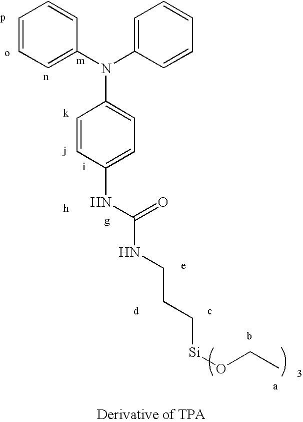

NMR ¹H (200 MHz, DMSO, 300 K): δ(ppm)=0.55 (t, 2H, ³J=8.3 H_{z}, H_{c}), 1.14 (t, 9H, ³J=7.3 H_{z}, Hₐ), 1.47 (p 2H, ³J=8.3 H_{z}, H_{d}), 3.03 (t, 2H, ³J=8.3 H_{z}, Hₑ), 3.74 (q, 6H, ³J=7.3 H_{z}, H_{b}), 6.14 (s, 1H, H_{f}), 6.94 (m, 8H, Hₖ+Hₙ+Hₚ), 7.28 (m, 6H, Hⱼ+Hₒ), 8.41 (s, 1H, Hₕ).
NMR ¹³C(¹H) (200 Mhz, DMSO, 300 K): δ(ppm)=8.4 (C_{c}), 19.4 (Cₐ), 24.5 (C_{d}), 42.1 (Cₑ), 56.9 (C_{b}), 119.9 (Cⱼ), 122.7 (Cₚ), 123.3 (Cₙ), 127.1 (Cₖ), 130.2 (Cₒ), 137.8 (Cⱼ), 141.1 (Cₗ), 148.4 (Cₘ), 156.1 (C_{g}).
MALDI-TOF: m/z=530.25 [M+Na]⁺, 316.16 [M—CH₂CH₂Si (OEt)₃]⁺.
HRMS (EI): calculated for C₂₈H₃₇N₃NaO₄Si 530.24455, found 530.24656 Err (ppm)−3.79.
IR (ATR, cm⁻¹): 3321 (ν N—H), 3062 (ν C—H_{Ar}), 2973 (νₐₛ C—H), 2873 (νₛ C—H), 1641 (ν C═O), 1597 and 1509 (ν C═C_{Ar}), 1565 (δ N—H), 1271 (ν C—N), 1235 (ν C—C), 1078 (ν_{as Si—O—C),} 957 (νₛ Si—O—C), 754 (γ C—H_{Ar}), 695 (γ cycle)
UV/vis (EtOH): λₘₐₓ/nm (ε/L.mol⁻¹.cm⁻¹, transition)=232 (14420, π→π′ E₂ band), 301 (25000, p→π).

2) Grafting of the TPA Derivative on Silicon Nanowires:

The p-doped silicon nanowires (B/Si=4.10⁻⁴), still carried by their growth substrate (1 cm² silicon wafer), are washed with ethanol and acetone, and the plate is then dried under argon. These p type silicon nanowires have an average length of 5 μm and an average diameter centred around 100 nm.

The plate is then immersed in a Piranha solution (H₂SO₄:H₂O₂ 70/30) for 15 min and then rinsed with deionized water and dried with argon. In a second activation step, the plate is exposed to UV radiation under ozone for 45 min and is then immersed in a solution of 1-(4-(diphenylamino)phenyl)-3-(3-(triethoxysilyl)propyl)urea in toluene (10⁻³ M), and the latter is heated at 80° C. for 4 h without stirring. After cooling, the plate is removed then rinsed with ethanol and acetone and dried with argon. The nanowires thus functionalized are degrafted in 1 ml toluene by sonication (power: 100%) for 1 min.

3) Dispersion of the Silicon Nanowires Functionalized By the TPA Derivative in the Organic Semiconductor Matrix αNPD:

The organic semiconductor matrix (small molecules) used in this example, to disperse the silicon nanowires functionalized by the TPA derivative, is α-(naphthyl)phenylenediamine (α-NPD).

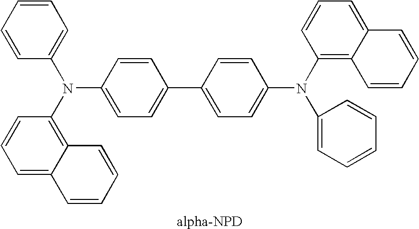

The suspension of silicon nanowires (1% weight of nanowires compared to α-NPD) is added to a solution containing 3 mg/ml of α-NPD in toluene. The electrical characterizations in transistor operation were carried out using low grid transistor supports and underside contact.
The hybrid semiconductor film (organic matrix with small α-NPD molecules+silicon nanowires functionalized by the TPA derivative) is obtained by slow evaporation and saturation vapour pressure of the hybrid semiconductor solution. The hybrid semiconductor is annealed at 100° C. for 20 minutes under nitrogen.
The transistors thus tested (having a W/L of 1000) display improved electrical performance with mobilities of the charge carriers (holes) of 2.4×10⁻⁴ cm²/Vs and an Ion/Ioff ratio of 10₃. The introduction of these functionalized nanocharges into the organic semiconductor matrix serves to improve the mobility by a factor of 4 compared to the matrix alone, without degrading the Ion/Ioff ratio.

### EXAMPLE 2

Manufacture of a transistor with a film of n type hybrid material with silicon nanowires grafted with a rylene derivative.

1) Synthesis and Grafting of the Dissymmetrical Perylene Diimide on the Silicon Nanowires:

The N-octyl-N′acetylenylphenylperylene-3,4,9,10-bis(dicarboximide) (PDT-8-acetylenylphenyl) is synthesized in three steps from 3,4,9,10-perylenetetracarboxylic dianhydride (PDA). One of the anhydride functions of the latter is opened by treatment in hot potassium hydroxide and phosphoric acid is then added to 5.5<pH<6.5 to obtain the monopotassium salt of perylene monoanhydride monoacid monocarboxylate. The addition of 4 equivalents of N-octylamine serves to obtain N-octyl-3,4,9,10-perylenetetracarboxylic acid-3,4-anhydride-9,10-imide (PAI-8) after purification by treatment in hot potassium hydroxide. Finally, the reaction of this perylene monoanhydride monoimide with 4 equivalents of ethynylaniline in toluene under reflux leads to the formation, after purification on silica column with a 90:10 chloroform/acetic acid mixture as eluant, of the desired product PDI-8-acetylenylphenyl in the form of a red solid with an overall yield of 44%.

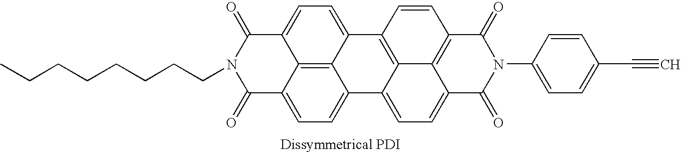

NMR ¹H (500 MHz, CDCl₃, 300 K): δ (ppm)=0.80 (t, 3H, CH₃), 1.32 (m, 10H, CH₂), 1.87 (m, 2H, NCH₂CH₂), 3.12 (s, 1H, CH), 4.21 (t, 2H, NCH₂), 7.53 (d, 2H, ³J =8. 1 H_{z}, CH_{Ar}), 7.78 (d, 2H, ³J=8.1 H_{z}, CH_{Ar}), 8.28 (d, 2H, ³J=8.1 H_{z}, CH_{perylene}), 8.39 (d, 2H_{z}, 3 =8.4 H_{z}, CH_{perylene}), 8.48 (d, 2H, ³J=8.4 H_{z}, CH_{perylene}) 8.60 (d, 2H, ³J=8.1 H_{z}, CH_{perylene}).
NMR ¹³C{¹H} (500 MHz, CDCl₃, 300 K): δ (ppm)=14.1(CH₃); 22.7; 26.7; 28.5; 29.3; 30.2; 31.8; 38.2; (7 C,CH₂); 81.4 (CH); 82.3 (C≡CH); 111.3 (CH_{Ar}); 118.3 (C_{Ar}); 124.5; 126.1; 126.7; 128.1; 128.4; 128.8; 129.2; 129.6; 130.4; 130.6; 130.9 131; 131.2; 135.2; 135.7; (23 C, C_{Ar}+CH_{Ar}+CH_{perylene}+C_{perylene}); 158.6; 159.3 (4 C, C═O).
IR (ATR, cm⁻¹): 3267 (νC—H), 3062 (νC—H_{Ar}), 2973 (νₐₛ C—H), 2873 (νₛ C—H), 2103 (ν C≡H), 1693 and 1652(ν C═O), 1597 and 1509 (ν C═C_{Ar}), 1271 (ν C—N), 1235 (ν C—C), 808 (γ C—H_{Ar}), 747 (γ cycle).

2) Grafting of Dissymmetrical Perylene Diimide on Silicon Nanowires:

The n-doped silicon nanowires (P/Si=2×10⁻⁴), still carried by their growth substrate (1 cm² silicon wafer), are washed with ethanol and acetone, and the plate is then dried under argon. These n type silicon nanowires have an average length of 4 μm and an average diameter centred around 100 nm.

The plate is then immersed in a dilute hydrofluoric acid solution (1%) for 2 min and then rinsed with deionized water. It is then immersed in a solution of ammonium fluoride (40%) for 2 min and then rinsed with deionized water and dried with argon. It is then introduced into a flask equipped with a cooler containing a solution of N-octyl-N′acetylenyl phenylperylene-3,4,9,10-bis(dicarboximide) in mesithylene (10⁻³ M) and the latter is heated to 180° C. for 2 h under argon without stirring. After cooling, the plate is removed then rinsed with ethanol and acetone and dried with argon. The nanowires thus functionalized are degrafted in 1 ml of ODCB (orthodichlorobenzene) by sonication (power 100%) for 1 min.

3) Dispersion of the Silicon Nanowires Functionalized by Dissymmetrical Perylene Diimide in the Organic Semiconductor Matrix PDI8-CN2:

The organic semiconductor matrix of the n type (small molecules) used in this example, to disperse the silicon nanowires functionalized by dissymmetrical PDI, is perylene diimide below:

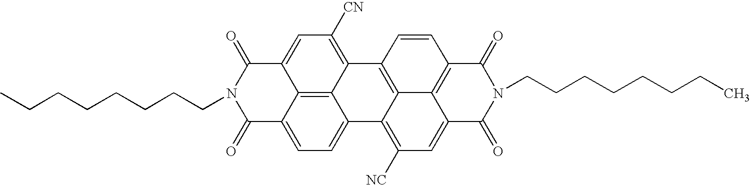

The suspension of silicon nanowires (1% by weight of nanowires compared to α-NPD) is added to a solution containing 4 mg/ml of PDI8-CN2 in ODCB. The electric characterizations in transistor operation were carried out using low grid transistor supports and underside contact.
The hybrid semiconductor film (organic matrix with small molecules PDI8-CN2+silicon nanowires functionalized by dissymmetrical PDI) is obtained by deposition by spin coater. The hybrid semiconductor is annealed at 100° C. for 20 minutes under nitrogen.
The transistors prepared with the organic matrix alone have mobilities of 1×10⁻³ cm²/Vs. The hybrid semiconductor transistors (having a W/L of 1000) have improved electrical performance with mobilities of the charge carriers (electrons) of 5×10⁻³ cm²/Vs and an Ion/Ioff ratio of 10⁴. The introduction of the functionalized n-doped Si nanowires into the organic semiconductor matrix serves to improve the mobility by a factor of 5 compared to the matrix alone, without degrading the Ion/Ioff ratio.

1. Hybrid semiconductor material of the type comprising an organic semiconductor matrix in which semiconductor nano-objects grafted by organic entities are dispersed, characterized in that the said organic matrix comprises small semiconductor molecules and in that the said organic entities grafted on semiconductor nano-objects have an active electrical function with a similar structure to that of the said small semiconductor molecules.

2. Material according to claim 1, characterized in that the said organic entities also have a function for covalent grafting of the said organic entities on the nano-object.

3. Material according to either of claims 1 and 2, characterized in that the nano-objects are nanowires.

4. Material according to claim 3, characterized in that the nanowires are silicon nanowires.

5. Material according to claim 3, characterized in that the nanowires are germanium-silicon nanowires.

6. Material according to claim 3, characterized in that the nanowires are nanowires of zinc oxide, ZnO.

7. Material according to claim 3, characterized in that the nanowires are nanowires of gallium arsenide, GaAs.

8. Material according to either of claims 1 and 2, characterized in that the nano-objects are carbon nanotubes.

9. Material according to either of claims 1 and 2, characterized in that the said nano-objects have at least two dimensions shorter than 100 nanometres and a length/diameter ratio above 10.

10. Device characterized in that it comprises a material according to any one of the preceding claims.

11. Device according to claim 10, characterized in that it is a transistor.
